(19) United States
(12) Patent Application Publication
(10) Pub. No.: US 2025/0063745 A1
(43) Pub. Date: Feb. 20, 2025

(54) PACKAGE STRUCTURE AND MANUFACTURING METHOD THEREOF

(71) Applicant: JCET GROUP CO., LTD., Jiangsu (CN)

(72) Inventors: Jianghua Zhang, Jiangsu (CN); Xianfang Yang, Jiangsu (CN)

(73) Assignee: JCET GROUP CO., LTD., Jiangsu (CN)

(21) Appl. No.: 18/795,130

(22) Filed: Aug. 5, 2024

(30) Foreign Application Priority Data
Aug. 14, 2023 (CN) 202311025089.2

(51) Int. Cl. H01L 25/16; H01L 23/00; H01L 23/29; H01L 23/31

(52) U.S. Cl. CPC H01L 28/10; H01L 23/29; H01L 24/08; H01L 25/16; H01L 23/3121; H01L 2224/08112; H01L 2224/08237; H01L 2924/1206

(57) ABSTRACT

Disclosed are a package structure and a manufacturing method thereof. The package structure incudes: a substrate, having a first surface and a second surface; a winding, disposed on the first surface of the substrate, and electrically connected to the substrate; a chip, disposed on the first surface of the substrate, and electrically connected to the substrate; a component, disposed on the first surface of the substrate, and electrically connected to the substrate; and a magnetic encapsulation layer, disposed on the first surface of the substrate, and encapsulating the winding, the chip, and the component.

### CROSS-REFERENCE TO RELATED APPLICATION

This application claims the priority benefit of China application serial no. 202311025089.2, filed on Aug. 14, 2023. The entirety of the above-mentioned patent application is hereby incorporated by reference herein and made a part of this specification.

### BACKGROUND

### Technical Field

The present disclosure relates to the field of semiconductors, and particularly relates to a package structure and a manufacturing method thereof.

### Description of Related Art

Power management chips are responsible for the conversion, distribution, detection, and other power management of electrical energy in the electronic equipment systems. The power management chips are indispensable to the electronic systems, and their performance has a direct impact on the performance of the entire machine.

Traditional power management chips, adopt a package method of ECP (also referred to as Embedded Chip Package, which refers to embedding the chip or device into the substrate) in order to reduce the package size, where the inductor is then mounted on the substrate. In the prior art, the chip package structure with inductor generates a lot of heat energy during long-term use. Since the chip is embedded in the substrate, its heat dissipation performance is poor and the heat dissipation speed is low, which can easily cause chip damage or aging, greatly reducing the service life of the chip.

### SUMMARY

In view of the above problems, the present disclosure proposes a package structure and a manufacturing method thereof.

The technical solution adopted by the present disclosure is as follows:

A package structure, including:
a substrate, having a first surface and a second surface;
a winding, disposed on the first surface of the substrate, and electrically connected to the substrate;
a chip, disposed on the first surface of the substrate, and electrically connected to the substrate;
a component, disposed on the first surface of the substrate, and electrically connected to the substrate; and
a magnetic encapsulation layer, disposed on the first surface of the substrate, and encapsulating the winding, the chip, and the component.

The magnetic encapsulation layer contains soft magnetic metal powder and has strong thermal conductivity. The magnetic encapsulation layer directly encapsulates the chip and can conduct heat well. The winding and the magnetic encapsulation layer form an inductor structure to realize an integrated package of the chip and the inductor. A distance between the chip and the inductor is smaller, which can achieve better power management performance and has lower package costs.

In some embodiments, the first surface of the substrate has a first pad, a second pad, and a third pad. The winding is connected to the first pad, the chip is connected to the second pad, and the component is connected to the third pad.

The winding, the chip, and the component can be connected to corresponding pads in a variety of ways, such as by coating or printing solder paste, flux, and other materials on the corresponding connection areas, and then welding them through various welding processes, such as reflow welding.

In some embodiments, a glue material is filled between the chip and the substrate.

Filling the glue material between the chip and the substrate can make the structure stronger and more reliable.

In some embodiments, the winding has a spiral portion and a connecting portion connected to the spiral portion. The connecting portion is electrically connected to the substrate, and at least one of the chip and the component is located in a space formed by the spiral portion.

In some embodiments, the chip and the component are both located in the space formed by the spiral portion.

Such a setting can reduce the product package size and increase the product design space. Smaller distances between the chip and the winding allow for better power management performance.

In some embodiments, the winding has the spiral portion and the connecting portion connected to the spiral portion. The connecting portion includes a vertical portion and a horizontal portion connected to each other. The connecting portion is electrically connected to the substrate through the horizontal portion.

The connecting portion is a pin of the winding, which is bent 90 degrees to form the horizontal portion. The horizontal portion is used to increase a projection area of the standing pin and improve the workability of the winding mounting.

In some embodiments, an outer diameter of the spiral portion is R, a length of the horizontal portion is L, and ¼≤R≤L≤R.

The present disclosure also discloses a manufacturing method of a package structure, including the following steps:
S1, providing a substrate, where the substrate has a first surface and a second surface, and the first surface of the substrate has a first pad, a second pad, and a third pad;
S2, providing a winding, a chip, and a component, where the winding is connected to the first pad, the chip is connected to the second pad, and the component is connected to the third pad; and
S3, disposing an insulating magnetic material on the first surface of the substrate, so that the insulating magnetic material encapsulates the winding, the chip, and the component to form a magnetic encapsulation layer.

In some embodiments, the insulating magnetic material may be a powder or a liquid, and may be formed by molding, potting, or other encapsulation methods.

In some embodiments, the step S2 further includes filling a glue material between the chip and the substrate.

In some embodiments, the winding has a spiral portion and a connecting portion connected to the spiral portion. The connecting portion is electrically connected to the first pad. At least one of the chip and the component is located in a space formed by the spiral portion.

In some embodiments, the winding has the spiral portion and the connecting portion connected to the spiral portion. The connecting portion includes a vertical portion and a horizontal portion connected to each other. The connecting portion is electrically connected to the first pad through the horizontal portion.

In some embodiments, an outer diameter of the spiral portion is R, a length of the horizontal portion is L, and ¼R≤L≤R.

The beneficial effects of the present disclosure are as follows: the magnetic encapsulation layer contains soft magnetic metal powder, the filler of the general encapsulation material is silicon dioxide, and the thermal conductivity of the soft magnetic metal powder is more than 5 times the thermal conductivity of silicon dioxide. Therefore, the magnetic encapsulation layer has strong thermal conductivity, and it directly encapsulates the chip and can conduct heat well. The winding and the magnetic encapsulation layer form the inductor structure to realize the integrated package of the chip and the inductor. The distance between the chip and the inductor is smaller, which can achieve better power management performance and has lower package costs.

### BRIEF DESCRIPTION OF THE DRAWINGS

FIG. 1 is a cross-sectional view of a package structure;

FIG. 2 is a top view of a package structure after a magnetic encapsulation layer is removed;

FIG. 3 is a top view of a winding;

FIG. 4 is a cross-sectional view along line A-A of FIG. 3;

FIG. 5 is a side view of a winding;

FIG. 6 is a side view of a winding from another angle;

FIG. 7 is a schematic view of a substrate;

FIG. 8 is a schematic view of a winding, a chip, and a component mounted on a basic first surface; and

FIG. 9 is a schematic view after a glue material is filled between a chip and a substrate.

### DESCRIPTION OF THE EMBODIMENTS

In order to make the purpose, technical solutions, and advantages of the embodiments of the present disclosure clearer, the technical solutions in the embodiments of the present disclosure will be clearly and completely described below with reference to the accompanying drawings in the embodiments of the present disclosure. Evidently, the embodiments to be described are some rather than all embodiments of the present disclosure. The components of the embodiments of the present disclosure generally described and illustrated in the accompanying drawings may be arranged and designed in a variety of different configurations.

In the description of the present disclosure, it should be understood that the terms “inside,” “outside,” and the like indicate orientations or position relationships which are based on the orientations or position relationships shown in the accompanying drawings, or the orientations or position relationships in which the product of the present disclosure is usually placed when in use, and these terms are merely for ease and brevity of the description, instead of indicating or implying that the devices or elements referred to shall have a particular orientation and shall be structured and operated based on the particular orientation. Accordingly, these terms shall not be construed as limiting the present disclosure. In addition, the terms “first,” “second,” and the like are merely for illustration purpose, and shall not be construed as indicating or implying a relative importance.

In the description of the present disclosure, unless otherwise explicitly specified and defined, the terms “disposed” and “connected” shall be understood in a broad sense, e.g., a fixed connection, a detachable connection, or an integral connection; or a direct connection, an indirect connection via an intermediate medium, or an internal connection between two elements. Persons of ordinary skill in the art may understand specific meanings of the above terms in the present disclosure according to the actual circumstances and contexts.

The present disclosure is described in detail below with reference to the accompanying drawings.

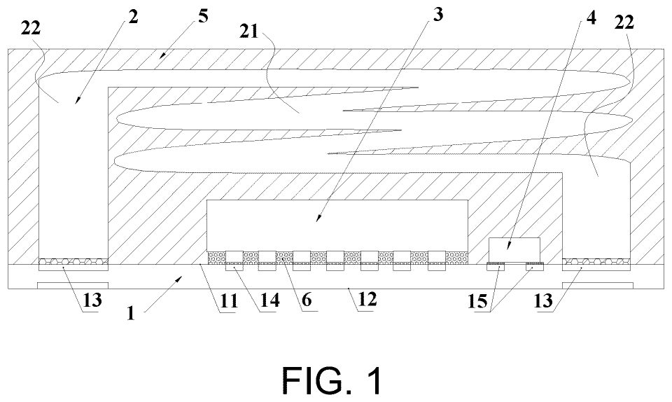

As shown in FIG. 1, a package structure includes:
a substrate 1, where the substrate 1 has a first surface 11 and a second surface 12;
a winding 2, disposed on the first surface 11 of the substrate 1 and electrically connected to the substrate 1;
a chip 3, disposed on the first surface 11 of the substrate 1 and electrically connected to the substrate 1;
a component 4, disposed on the first surface 11 of the substrate 1 and electrically connected to the substrate 1;
a magnetic encapsulation layer 5, disposed on the first surface 11 of the substrate 1, and encapsulating the winding 2, the chip 3, and the component 4.

In some embodiments, the winding 2 and the magnetic encapsulation layer 5 form an inductor structure.

In some embodiments, the chip may include a power management chip.

In some embodiments, the winding may be a normal metal coil, or may be an enameled wire coated with an insulating varnish.

In some embodiments, the magnetic encapsulation layer includes soft magnetic metal powder, and the ferromagnetic material commonly includes iron (Fe), cobalt (Co), nickel (Ni), or an alloy combination thereof.

As shown in FIG. 1, in some embodiments, the first surface 11 of the substrate 1 has a first pad 13, a second pad 14, and a third pad 15. The winding 2 is connected to the first pad 13, the chip 3 is connected to the second pad 14, and the component 4 is connected to the third pad 15.

The winding 2, the chip 3, and the component 4 can be connected to the corresponding pads in various ways, such as by coating or printing solder paste, flux, and other materials on the corresponding connection areas, and then welding them through various welding processes, such as reflow welding.

As shown in FIG. 1, in some embodiments, a glue material 6 is filled between the chip 3 and the substrate 1. Filling the glue material 6 between the chip 3 and the substrate 1 can make the structure more solid and more reliable.

As shown in FIG. 1, in some embodiments, the winding 2 has a spiral portion 21 and a connecting portion 22 connected to the spiral portion 21. The connecting portion 22 is electrically connected to the substrate 1.

In some embodiments, at least one of the chip 3 and the component 4 is located in a space formed by the spiral portion 21.

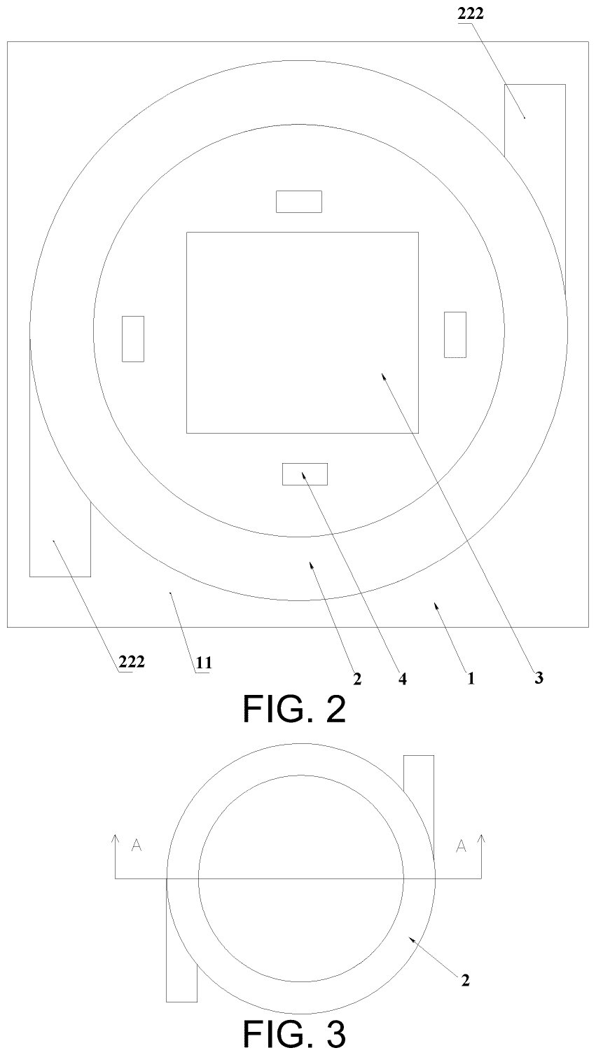

As shown in FIG. 1 and FIG. 2, in some embodiments, the chip 3 and the component 4 are both located in the space formed by the spiral portion 21. Such a setting can reduce the product package size and increase the product design space. A distance between the chip 3 and the winding 2 is smaller, which can achieve better power management performance.

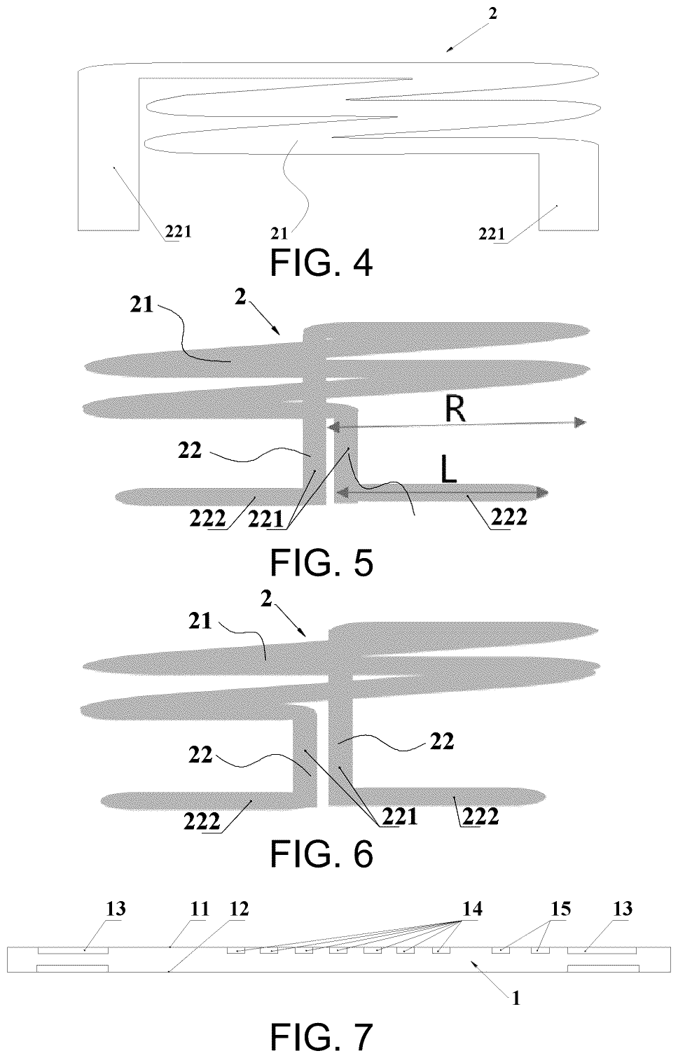

As shown in FIG. 1, FIG. 2, FIG. 3, FIG. 4, FIG. 5, and FIG. 6, in some embodiments, the winding 2 has the spiral portion 21 and the connecting portion 22 connected to the spiral portion 21. The connecting portion 22 includes a vertical portion 221 and a horizontal portion 222 connected to each other. The connecting portion 22 is electrically connected to the substrate 1 through the horizontal portion 222. The connecting portion 22 is a pin of the winding, which is bent 90 degrees to form the horizontal portion 222. The horizontal portion 222 is used to increase a projection area of the standing pin and improve the workability of the winding mounting.

As shown in FIG. 5, in some embodiments, an outer diameter of the spiral portion 21 is R, a length of the horizontal portion 222 is L, and ¼R≤L≤R. Such a design can ensure the winding function without increasing the winding size, and can better allow the winding to stand and remain stable.

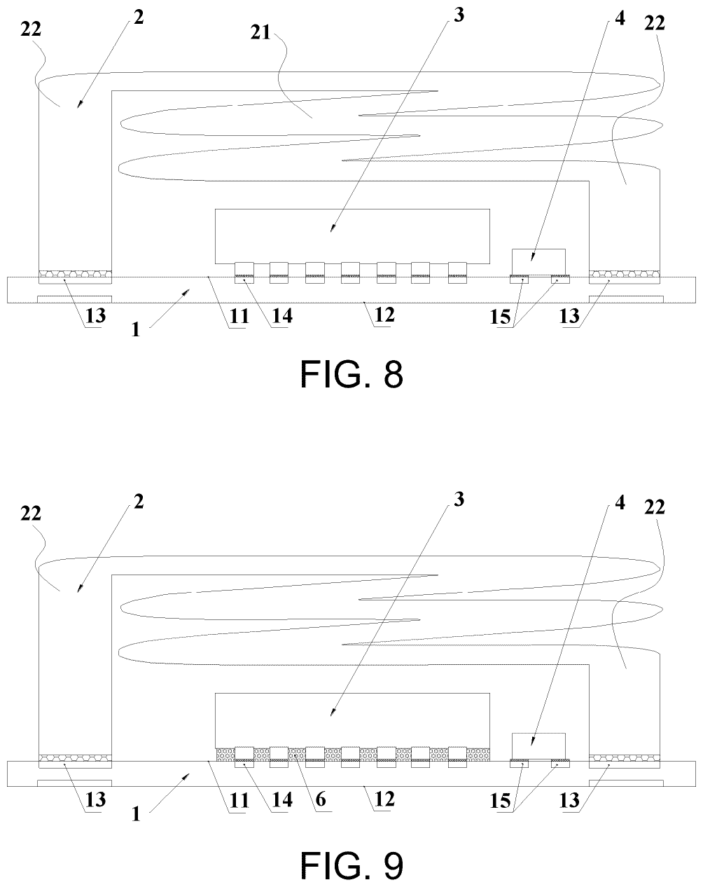

The embodiment also discloses a manufacturing method of a package structure, including the following steps:
S1, referring to FIG. 7, providing the substrate 1, where the substrate 1 has the first surface 11 and the second surface 12, and the first surface 11 of the substrate 1 has the first pad 13, the second pad 14, and the third pad 15;
S2, referring to FIG. 8, providing the winding 2, the chip 3, and the component 4, where the winding 2 is connected to the first pad 13, the chip 3 is connected to the second pad 14, and the component 4 is connected to the third pad 15; and
S3, referring to FIG. 1, disposing an insulating magnetic material on the first surface 11 of the substrate 1, so that the insulating magnetic material encapsulates the winding 2, the chip 3, and the component 4 to form the magnetic encapsulation layer 5.

In some embodiments, the insulating magnetic material may be powder or liquid, and may be formed by molding, potting, or other encapsulation methods.

As shown in FIG. 9, in some embodiments, the step S2 further includes filling the glue material 6 between the chip 3 and the substrate 1.

In some embodiments, the manufacturing method of the package structure is used to manufacture the package structure of FIG. 1.

In the package structure of the present disclosure, the magnetic encapsulation layer 5 contains the soft magnetic metal powder and has strong thermal conductivity. The magnetic encapsulation layer 5 directly encapsulates the chip 3, and can conduct heat well. The winding 2 and the magnetic encapsulation layer 5 form the inductor structure to realize the integrated package of the chip 3 and the inductor. The distance between the chip and the inductor is smaller, which can achieve better power management performance and has lower package costs.

The above description is only a preferred embodiment of the present disclosure, and does not limit the patent protection scope of the present disclosure. Any equivalent structural transformation made by using the contents of the present disclosure and the drawings, directly or indirectly used in other related technical fields, is also included in the protection scope of the present disclosure.

What is claimed is:

1. A package structure, comprising:
a substrate having a first surface and a second surface;
a winding disposed on the first surface of the substrate, and electrically connected to the substrate;
a chip disposed on the first surface of the substrate, and electrically connected to the substrate;
a component disposed on the first surface of the substrate, and electrically connected to the substrate; and
a magnetic encapsulation layer disposed on the first surface of the substrate, and encapsulating the winding, the chip, and the component.

2. The package structure according to claim 1, wherein the first surface of the substrate has a first pad, a second pad, and a third pad, the winding is connected to the first pad, the chip is connected to the second pad, and the component is connected to the third pad.

3. The package structure according to claim 2, wherein the winding and the magnetic encapsulation layer form an inductor structure.

4. The package structure according to claim 1, wherein the winding has a spiral portion and a connecting portion connected to the spiral portion, the connecting portion is electrically connected to the substrate, and at least one of the chip and the component is located in a space formed by the spiral portion.

5. The package structure according to claim 4, wherein the chip and the component are both located in the space formed by the spiral portion.

6. The package structure according to claim 1, wherein the winding has a spiral portion and a connecting portion connected to the spiral portion, the connecting portion comprises a vertical portion and a horizontal portion connected to each other, and the connecting portion is electrically connected to the substrate through the horizontal portion.

7. The package structure according to claim 6, wherein an outer diameter of the spiral portion is R, a length of the horizontal portion is L, and ¼R≤L≤R.

8. A manufacturing method of a package structure, comprising the following steps:
step S1, providing a substrate, wherein the substrate has a first surface and a second surface, and the first surface of the substrate has a first pad, a second pad, and a third pad;
step S2, providing a winding, a chip, and a component, connecting the winding to the first pad, connecting the chip to the second pad, and connecting the component to the third pad; and
step S3, disposing an insulating magnetic material on the first surface of the substrate, so that the insulating magnetic material encapsulates the winding, the chip, and the component to form a magnetic encapsulation layer.

9. The manufacturing method of the package structure according to claim 8, wherein the step S2 further comprises filling a glue material between the chip and the substrate.

10. The manufacturing method of the package structure according to claim 8, wherein the winding has a spiral portion and a connecting portion connected to the spiral portion, the connecting portion is electrically connected to the first pad, and at least one of the chip and the component is located in a space formed by the spiral portion.

11. The manufacturing method of the package structure according to claim 8, wherein the winding has a spiral portion and a connecting portion connected to the spiral portion, the connecting portion comprises a vertical portion and a horizontal portion connected to each other, and the connecting portion is electrically connected to the first pad through the horizontal portion.

12. The manufacturing method of the package structure according to claim 11, wherein an outer diameter of the spiral portion is R, a length of the horizontal portion is L, and ¼R≤L≤R.
